(19) United States
(12) Patent Application Publication
(10) Pub. No.: US 2006/0255435 A1
(43) Pub. Date: Nov. 16, 2006

(54) Method for encapsulating a semiconductor device and semiconductor device

(76) Inventors: Edward Fuergut, Dasing (DE); Holger Woerner, Regensburg (DE)

Correspondence Address: DICKE, BILLIG & CZAJA, P.L.L.C., FIFTH STREET TOWERS, 100 SOUTH FIFTH STREET, SUITE 2250, MINNEAPOLIS, MN, 55402, US

(21) Appl. No.: 11/388,551

(22) Filed: Mar. 24, 2006

(30) Foreign Application Priority Data
Mar. 24, 2005 (DE) 10 2005 014 427.6

(51) Int. Cl. H01L 23/495

(52) U.S. Cl. 257/666

(57) ABSTRACT

One aspect of the invention relates to a method for encapsulating a semiconductor device which has at least one semiconductor chip arranged on a substrate. The method includes application of an elastic dam to the semiconductor chip, introduction of the semiconductor chip arranged on the substrate into a mold including a lower mold half and an upper mold half, closing of the mold so that the elastic dam is completely contacted by an inner surface of the upper mold half, and encapsulation of the semiconductor device with a molding compound.

### CROSS-REFERENCE TO RELATED APPLICATIONS

This Utility Patent Application claims priority to German Patent Application No. DE 10 2005 014 427.7, filed on Mar. 24, 2005, which is incorporated herein by reference.

### BACKGROUND

One embodiment of the present invention relates to a method, such as a transfer molding method, for encapsulating a semiconductor device and to a semiconductor device which is produced by means of the method.

In the prior art it is known to encapsulate semiconductor chips by means of a transfer molding method. To keep the surface on the semiconductor chip free from the material of the package or to seal it from the material of the package during the transfer molding method, as is necessary for example in the case of fingertip sensors, biosensors, BAW/SAW filters, the most popular variant used for sealing a surface has previously been that of film molding.

In this case, a film is stretched over the upper half of the mold and, when the two mold halves are clamped, is compressed in such a way that it undertakes a sealing function. However, this method only allows very broad tolerances, entails a high risk of wire damage and only has a low capacity to compensate for variations in chip thickness, since the film used cannot compensate for great variations.

Furthermore, the prior art discloses a method for producing IC sensor packages which uses a flexible layer which is fixed in the mold and undertakes the sealing of the surface of the IC that is to be kept free. However, a product-specific mold has to be used. In addition, with this method there is a problem with respect to the wear of the highly stressed flexible layer, since it is used under high pressures and high temperatures.

In the case of another method known from the prior art, which is similar to the method described above, the flexible material is not attached over the full surface area but merely in the form of a frame. Here, however, the same disadvantages as when the full-area flexible layer is used also arise.

Mold designs in which a sprung plate or a punch undertakes the sealing are also known. Disadvantages here are the both complex and sensitive construction and problems in sealing the guides, which leads to rapid seizing of the punches.

On account of the aforementioned problems, what is known as a dam & fill dispensing method is often used instead of a molding method. However, this method is disadvantageous with respect to geometrical dimensional stability, tolerances, available materials and process control.

### SUMMARY

One embodiment of the present invention provides a method for encapsulating semiconductor devices and a semiconductor device produced by means of the method, the method not requiring any specific mold but ensuring reliable sealing of any regions that are to be sealed.

Accordingly, one embodiment of the invention provides a method for encapsulating a semiconductor device which has at least one semiconductor chip arranged on a substrate. One embodiment of the method includes the following steps: application of an elastic dam to the semiconductor chip; introduction of the semiconductor chip arranged on the substrate into a mold comprising a lower mold half and an upper mold half; closing of the mold, so that the elastic dam is completely contacted by an inner surface of the upper mold half, and encapsulation of the semiconductor device with a molding compound. By means of the method according to the invention, the sealing function is consequently no longer accomplished on the mold but on the surface area to be sealed, that is, on the semiconductor device or on the semiconductor chip.

Accordingly, the dam, which consists of an elastic material, is applied to the semiconductor chip in such a way that it runs all the way around the surface area to be sealed. During the molding operation or during the closing of the upper and lower mold halves, this dam is compressed by a defined amount on account of its elasticity. This has the effect of producing over the surface area to be sealed a closed cavity, into which no molding compound can flow. The desired regions are therefore kept free from the molding compound in a simple way and without using a specific mold.

Furthermore, the mold also cannot become worn in the same way as those which are used in the prior art. The method according to one embodiment of the invention can in principle be used for any type of “exposed die packages” in which part of the chip area must be kept free from molding compound.

As already mentioned, typical examples of this are fingertip sensors, biosensors and BAW/SAW filters, but also packages in which a heat spreader is to be contacted directly on the silicon. A further application is that of “land-on-top” (LOT) packages, in which terminal areas for the mounting of a further package have to be provided on the upper side of the package. Consequently, the method according to embodiments of the invention can be used in a versatile and variable manner.

According to one exemplary embodiment, the method further includes the step of fixing the at least one semiconductor chip on the substrate, for example, by adhesive attachment.

In one case the method includes the step of bonding the semiconductor chip, for example, die-wire bonding.

The application of the elastic dam is in one case carried out by means of known methods such as dispensing, printing or by using preforms.

According to a further exemplary embodiment, the method further includes the step of curing the molding compound.

In one embodiment the step of closing the mold is performed by using pressure, so that the dam is compressed by a defined amount on account of its elasticity. In this way, high tolerances of the surface areas to be sealed can also be compensated during the molding operation by the elasticity of the dam.

According to yet another exemplary embodiment of the method, a thermoplastic material, for example, epoxy resin, is used as the molding compound.

An elastic polymer material is used in one case as the dam material, for example, silicone or polyurethane may be used.

According to another exemplary embodiment, rubber is used as the dam material.

The dam is in one case applied to the semiconductor chip in such a way that it runs all the way around a surface area to be sealed. The height of the dam is likewise to be chosen in such a way as to make allowance, and thereby compensate, for tolerances of the heights of the device.

Furthermore, in one embodiment the dam, the surface area of the chip that is to be sealed and part of the inner surface of the upper mold half of the mold form a closed cavity which is sealed with respect to molding compound when the mold is closed.

The substrate in one case has a first surface and a second surface, opposite from the first surface, the semiconductor chip being applied to the first surface of the substrate.

According to a further exemplary embodiment, the substrate rests with its second surface on an inner surface of the lower mold half of the mold.

In addition, the semiconductor chip has a first surface and a second surface, opposite from the first surface, the dam being formed on the first surface of the semiconductor chip.

The semiconductor chip is in one case fixed with its second surface on the first surface of the substrate.

In one embodiment, the step of encapsulating the semiconductor device is carried out by means of a transfer molding method.

One embodiment of the invention also provides a semiconductor device, which has a semiconductor chip applied to a substrate and encapsulated in a package, the semiconductor chip and the substrate respectively having a first surface and a second surface, the semiconductor chip resting with its second surface on the second surface of the substrate, the semiconductor chip having on its first surface a dam delimiting a surface area to be sealed.

The semiconductor device may have a leadframe, to which the semiconductor chip is bonded by means of lead wires.

Yet another embodiment of the semiconductor device provides that the semiconductor chip is adhesively attached on the substrate.

The package of the semiconductor device is in one case formed by means of a transfer molding method.

According to yet another embodiment, the package of the semiconductor device is produced from a thermoplastic material, for example, from epoxy resin.

In one embodiment the dam is produced from an elastic material, for example, from an elastic polymer material.

In one embodiment, materials from which the dam of the semiconductor device is produced are silicone or polyurethane.

Alternatively, however, the dam may also be produced from rubber.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 illustrates a schematic cross section through a semiconductor device and an upper mold half, as used in the prior art.

FIG. 2 illustrates a schematic cross section through a semiconductor device and a further upper mold half, as used in the prior art.

FIG. 3 illustrates a schematic cross section through a semiconductor device and yet another upper mold half according to the prior art.

FIG. 4 illustrates a schematic cross section through a semiconductor device and a mold half according to the prior art.

FIG. 5 illustrates a schematic cross section through a substrate with semiconductor chips.

FIG. 6 illustrates a schematic cross section through a substrate with semiconductor chips which is introduced into a mold.

FIG. 7 illustrates a schematic cross section through a substrate with semiconductor chips in a mold which is closed.

FIG. 8 illustrates a schematic cross section through a substrate with semiconductor chips in a closed mold during the encapsulating operation.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

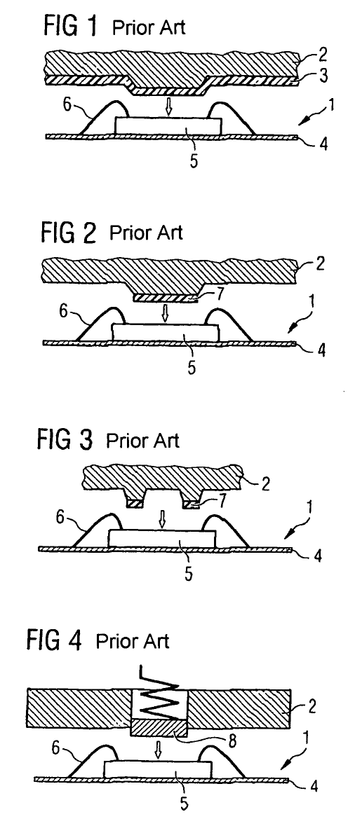

FIG. 1 illustrates a schematic cross section through a semiconductor device 1, which has a semiconductor chip 5 arranged or adhesively attached on a substrate 4. The semiconductor chip 5 is electrically connected to contact areas (not shown) on the substrate 4 by means of lead wires 6. Arranged over the semiconductor device 1 is an upper mold half 2, as popularly used in the prior art for sealing during what is known as film molding. In this case, a film 3 is stretched in the upper mold half 2. When the substrate 4 is clamped between the upper mold half 2 and the lower mold half (not shown) during closing of the two mold halves, the film 3 is stretched in such a way that it undertakes a sealing function, so that during the encapsulating operation the part of the surface of the semiconductor chip 5 which is contacted by the film 3 is kept free from molding compound, such as for example epoxy resin.

FIG. 2 illustrates a schematic cross section through a semiconductor device and a further upper mold half, as used in the prior art. As also in FIG. 1, a semiconductor device 1 is arranged underneath an upper mold half 2; the lower mold half is also not illustrated in this figure. The method differs from the film molding method represented in FIG. 1 in that, instead of the film 3, a flexible layer 7 is used for sealing the region to be kept free on the surface of the semiconductor chip 5. The flexible layer 7 is fixed to the product-specifically formed upper mold half 2 and is consequently exposed to high stress, that is, high pressures and high temperatures, during the molding process.

FIG. 3 illustrates another schematic cross section through a semiconductor device 1, as already described in connection with FIG. 1. Arranged over it is a further upper mold half 2, known from the prior art, which differs from the design represented in FIG. 2 merely in that the flexible layer 7 is not attached to the upper mold half 2 over the full surface area but only in the form of a frame. However, this flexible layer 7 is also exposed to the same high stresses as the full-area flexible layer 7 of FIG. 2.

In FIG. 4 there is illustrated a schematic cross section through a semiconductor device 1, as described in connection with FIG. 1, and a further upper mold half 2 according to the prior art. This mold differs from the mold designs described above in that here a sprung plate 8 undertakes the sealing of part of the surface of the semiconductor chip 5 when the upper mold half 2 and the lower mold half (not shown) are closed and the encapsulating operation takes place.

FIGS. 5 to 8 respectively illustrate schematic cross sections through a substrate 4 with semiconductor chips 5 arranged on it during various method steps of the method according to embodiments of the invention. FIG. 5 illustrates two semiconductor chips 5 arranged on a substrate 4, which are already connected to the substrate 4 by means of lead wires 6. The semiconductor chips 5 respectively have a first surface 9 and a second surface 10, which is opposite from the first surface 9. The substrate 4 likewise has a first surface 12 and a second surface 13, opposite from the first surface 12. The semiconductor chips 5 are adhesively attached with their respective second surfaces 10 on the first surface 12 of the substrate. On their respective first surfaces 9, an elastic material, here silicone, is applied by means of a dispensing method in the form of a dam 11 running all the way around.

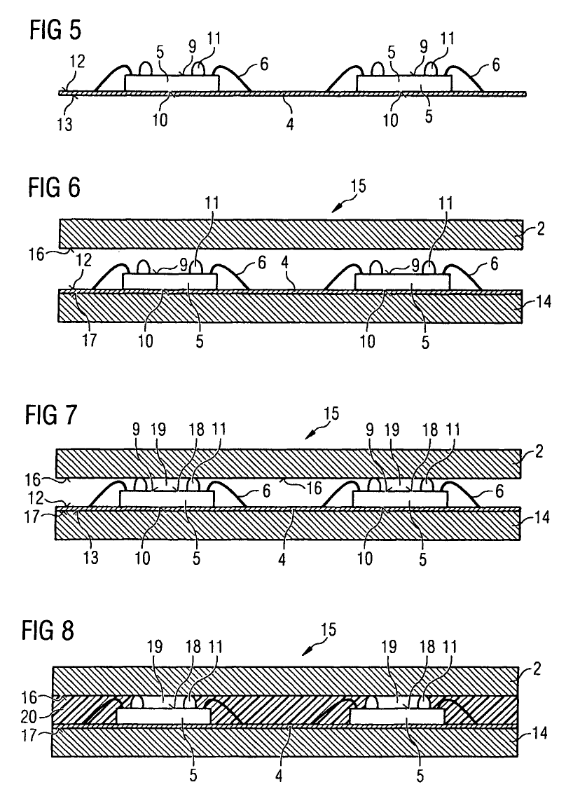

In FIG. 6 there is illustrated a further method step, in which the substrate 4 with the semiconductor chips 5 attached on it is arranged in a customary mold 15, as used for the transfer molding method. The mold 15 includes an upper mold half 2, which has an inner surface 16, and a lower mold half 14, which likewise has an inner surface 17. The substrate 4 rests with its second surface 13 on the inner surface 17 of the lower mold half 14. The upper mold half 2 is arranged above the semiconductor chips 5, but does not contact them yet.

In the next step, which is illustrated in FIG. 7, the mold 15 is closed, so that now the inner surface 16 of the upper mold 2 contacts the elastic dam 11, which is respectively applied to the first surface 9 of the semiconductor chips 5, or compresses it by a defined amount on account of its elasticity. This has the effect of producing over a surface area 18 to be sealed on the semiconductor chips 5 a closed cavity 19, into which no molding compound can flow during the encapsulating process. Tolerances or unevennesses on the surface of the semiconductor chip 5 are compensated by the chosen height of the dam 11.

Finally, in FIG. 8 there is illustrated the situation after the encapsulating operation, during which epoxy resin has been filled into the closed mold 15 in order to encapsulate the semiconductor chips 5. The epoxy resin is cured; after that, the mold 15 can then be removed. It is evident that no molding compound has flowed into the cavity 19, which is delimited by the dam 11, part of the inner surface 16 of the upper mold half 2 and the surface area 18 to be sealed on the semiconductor chip 5, and the desired regions are kept free, which has consequently been achieved in a simple way by means of conventional, product-unspecific molds. Wear of the sealing function cannot occur in the case of the method according to the invention, since this does not occur in the mold 15 but on the semiconductor chip 5 itself. In this way, each seal is stressed only once and longer mold service lives, and consequently also lower production costs, can be achieved by means of the method according to embodiments of the invention.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A method for encapsulating a semiconductor device which comprises at least one semiconductor chip arranged on a substrate, the method comprising:
applying an elastic dam to the semiconductor chip;
introducing the semiconductor chip arranged on the substrate into a mold comprising a lower mold half and an upper mold half;
closing the mold so that the elastic dam is completely contacted by an inner surface of the upper mold half; and
encapsulating the semiconductor device with a molding compound.

2. The method of claim 1, further comprising fixing the at least one semiconductor chip on the substrate, and adhesive attachment of the at least one semiconductor chip on the substrate.

3. The method of claim 1, further comprising bonding the semiconductor chip, and die-wire bonding.

4. The method of claim 1, wherein the application of the dam is performed by dispensing, printing or using preforms.

5. The method of claim 1, further comprising curing the molding compound.

6. The method of claim 1, wherein closing the mold is performed by using pressure so that the dam is compressed by a defined amount on account of its elasticity.

7. The method of claim 1, a thermoplastic epoxy resin is used as the molding compound.

8. The method of claim 1, wherein an elastic polymer material, from the group comprising silicone and polyurethane, is used as the dam material.

9. The method of claim 1, wherein rubber is used as the dam material.

10. The method of claim 1, wherein the dam is applied to the semiconductor chip in such a way that it runs all the way around a surface area to be sealed.

11. The method of claim 10, wherein the dam, the surface area of the semiconductor chip that is to be sealed and part of the inner surface of the upper mold half of the mold form a closed cavity which is sealed with respect to molding compound when the mold is closed.

12. The method of claim 1, wherein the substrate comprises a first surface and a second surface, opposite from the first surface, the semiconductor chip being applied to the first surface of the substrate.

13. The method of claim 12, wherein the substrate rests with its second surface on an inner surface of the lower mold half of the mold.

14. The method of claim 1, the semiconductor chip comprising a first surface and a second surface, opposite from the first surface, the dam being formed on the first surface of the semiconductor chip.

15. The method of claim 14, wherein the semiconductor chip is fixed with its second surface on the first surface of the substrate.

16. The method of claim 1, wherein encapsulating the semiconductor device is carried out by means of a transfer molding method.

17. A semiconductor device comprising:
a semiconductor chip applied to a substrate and encapsulated in a package, the semiconductor chip and the substrate respectively having a first surface and a second surface;
wherein the semiconductor chip rests with its second surface on the second surface of the substrate; and
wherein the semiconductor chip comprises on its first surface a dam delimiting a surface area to be sealed.

18. The semiconductor device of claim 17, wherein it also has a leadframe, to which the semiconductor chip is bonded by means of lead wires.

19. The semiconductor device of claim 17, wherein the semiconductor chip is adhesively attached on the substrate.

20. The semiconductor device of claim 17, wherein the package is formed by means of a transfer molding method.

21. The semiconductor device of claim 17, wherein the package is produced from a thermoplastic epoxy resin.

22. The semiconductor device of claim 17, wherein the dam is produced from an elastic polymer material.

23. The semiconductor device of claim 22, wherein the dam is produced from silicone or polyurethane.

24. The semiconductor device of claim 17, wherein the dam is produced from rubber.
